(19) United States
(12) Patent Application Publication
(10) Pub. No.: US 2026/0002975 A1
(43) Pub. Date: Jan. 1, 2026

(54) JIG MODULE AND CIRCUIT BOARD TESTING METHOD USING THE SAME

(71) Applicant: WISTRON NEWEB CORPORATION, HSINCHU (TW)

(72) Inventors: Yong-Jyun Lu, HSINCHU (TW); CHE-MING WANG, HSINCHU (TW)

(21) Appl. No.: 19/008,712

(22) Filed: Jan. 3, 2025

(30) Foreign Application Priority Data
Jun. 28, 2024 (TW) 113124217

(51) Int. Cl. G01R 31/28; G01R 1/067; G01R 1/073

(52) U.S. Cl. CPC G01R 31/2808; G01R 1/06727; G01R 1/07371

(57) ABSTRACT

A jig module and circuit board testing method using thereof are provided. The jig module includes a guiding jig. The guiding jig is disposed inside a mechanism element along a travel direction, and a circuit board is disposed inside the mechanism element. The guiding jig includes a platform, a first alignment structure, and a second alignment structure. The platform has a top and a bottom, and the platform includes a plurality of through holes penetrating the top surface and the bottom surface. When the guiding jig is disposed inside the mechanism element, the first alignment structure aligns with the mechanical component along a first direction and a second direction, and the second alignment structure aligns with the circuit board along a third direction, such that the plurality of through holes can be aligned with a plurality of test points on the circuit board.

### CROSS-REFERENCE TO RELATED PATENT APPLICATION

This application claims the benefit of priority to Taiwan Patent Application No. 113124217, filed on Jun. 28, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a jig module and a circuit board testing method, in particular to a jig module and a circuit board testing method capable of aligning circuit boards inside a mechanism element.

### BACKGROUND OF THE DISCLOSURE

Currently, during the production process of system products, circuit boards will be tested after completing Pick and Place. Generally speaking, the circuit board at this time has not yet been assembled into a mechanism element. The circuit board will be placed onto a jig stage where test points on the circuit board are aligned with the jig stage, so as to allow a probe connected to a testing instrument to be pressed down to electrically contact the test points on the PCBA for testing.

The reason why testing cannot be performed after assembling the circuit board into the mechanism element is that a circuit board placed inside the mechanism element will be surrounded by the structure inside the mechanism element, which reduces the empty space around the test points and increases the travel distance for pressing down the probe, thereby increasing the difficulty of aligning the probe to the test points, causing a reduction on the yield of successful testing. However, in existing techniques, the procedure of first placing the circuit board on the jig carrier for testing, and then assembling the circuit board into the mechanism element after testing is unfavorable to the optimization of production processes, and causes the arrangement of testing stations to be rather restrictive and inflexible; therefore, there exists a problem of poor production efficiency.

### SUMMARY OF THE DISCLOSURE

The present disclosure mainly provides a jig module and a circuit board testing method to solve the problem of poor efficiency existing among circuit board testing processes in prior art.

In order to solve the above technical problems, one of the technical solutions adopted by the present disclosure is to provide a jig module, which includes a guiding jig. The guiding jig is disposed inside the mechanism element along a travel direction, the mechanism element having a circuit board disposed therein. The guiding jig comprises a platform, a first alignment structure and a second alignment structure. The platform has a top and a bottom, the platform including a plurality of through holes penetrating the top and the bottom. A first alignment structure and a second alignment structure are respectively disposed on the top and the bottom of the platform. When the guiding jig is disposed inside the mechanism element, the first alignment structure and the mechanism element align along a first direction and a second direction, the second alignment structure and the circuit board align along a third direction, such that the plurality of through holes are aligned with a plurality of test points on the circuit board. The first direction, the second direction and the third direction are perpendicular to each other, and the third direction is parallel to the travel direction.

In order to solve the above technical problems, another technical solution adopted by the present disclosure is to provide a circuit board testing method, which comprises at least the following steps: providing a guiding jig, the guiding jig being disposed inside the mechanism element along a travel direction, the mechanism element having a circuit board disposed therein, the guiding jig comprising a platform, a first alignment structure and a second alignment structure, the platform including a plurality of through holes penetrating a top and a bottom of the platform, the first alignment structure and the second alignment structure respectively being disposed on the top and the bottom of the platform; adjusting the first alignment structure and the mechanism element to align along a first direction and a second direction; adjusting the second alignment structure and the circuit board to align along a third direction, such that the plurality of through holes are aligned with a plurality of test points on the circuit board, wherein the first direction, the second direction and the third direction are perpendicular to each other, and the third direction is parallel to the travel direction; providing a probe carrier to carry a plurality of probe components; and assembling the probe carrier to the guiding jig, such that the plurality of probe components respectively pass through the plurality of through holes, and are respectively electrically connected to the plurality of test points.

One of the beneficial effects of the present disclosure is that, the jig module and circuit board testing method provided by the present disclosure can place the guiding jig inside the mechanism element, and use the first alignment structure of the guiding jig to align with the mechanism element in the first direction and the second direction, and the second alignment structure of the guiding jig to align with the mechanism element in the third direction, such that the multiple through holes can be aligned with a plurality of test points on the circuit board. Through the jig module and circuit board testing method of the present disclosure, the probe components can be directly extended into the interior of the mechanism element and be inserted into a plurality of through holes to contact the test points for performing electrical testing. Therefore, compared to prior art, the goal of electrical testing with probe components can be achieved even if the circuit board is placed inside the mechanism element.

In order to further understand the features and technical aspects of the present disclosure, please refer to the following detailed description and drawings of the present disclosure; however, the drawings provided are only for reference and illustration, and are not used to limit the present disclosure.

The above and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a circuit board inside a guiding jig alignment mechanism according to the present disclosure.

FIG. 2 is a schematic view of a probe carrier carrying probe components aligned with a circuit board through a guiding jig according to the present disclosure.

FIG. 3 is a schematic top view of the jig module being inserted into a mechanism element according to the present disclosure.

FIG. 4 is a schematic cross-sectional view of the guiding jig being inserted into the mechanism element according to the present disclosure.

FIG. 5 is an enlarged schematic view of the V portion in FIG. 4.

FIG. 6 is a schematic view of the probe carrier according to the present disclosure.

FIG. 7 is a schematic cross-sectional view of the probe carrier according to the present disclosure.

FIG. 8 is another schematic view of the probe carrier according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. In addition, the term “connect” used in the entirety of the present disclosure means that there is a physical connection between two elements and is a direct connection or an indirect connection.

### EMBODIMENTS

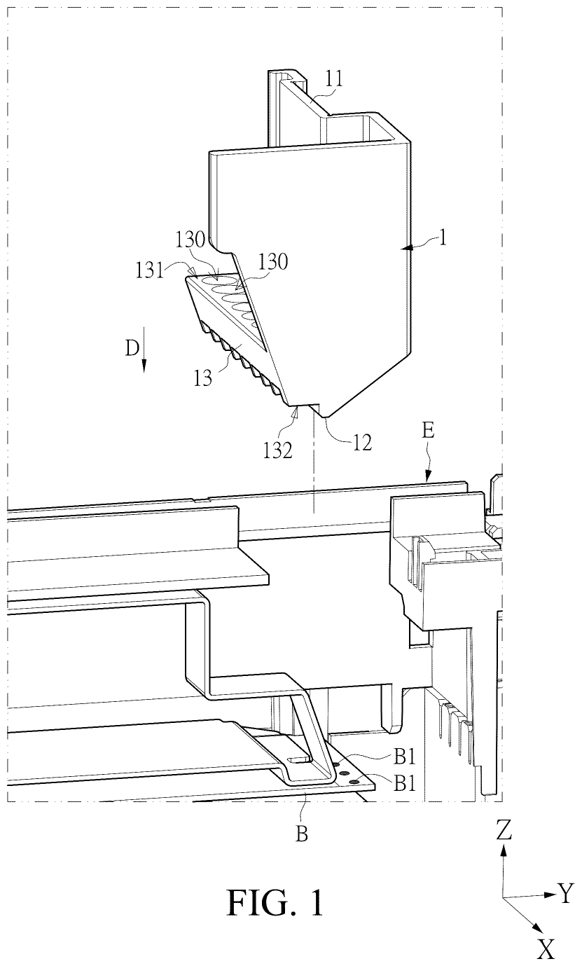

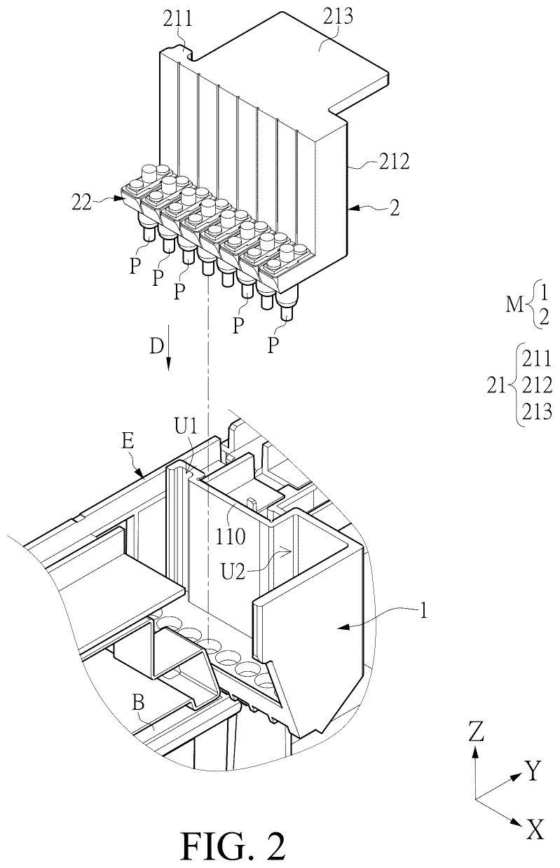

Referring to FIGS. 1 and 2, FIG. 1 is a schematic view of the circuit board inside the alignment mechanism of the guiding jig according to the present disclosure. FIG. 2 is a schematic view of the probe carrier carrying probe components aligning with the circuit board through the guiding jig according to the present disclosure. The present disclosure provides a jig module M (see FIG. 2), which is adapted for electrical testing between the probe components P and the circuit board B inside the mechanism element E.

The jig module M includes a detachable guiding jig 1 and a probe carrier 2. The guiding jig 1 is arranged inside the mechanism element E along a travel direction D. The guiding jig 1 includes a platform 13, and a first alignment structure 11 and a second alignment structure 12 disposed on the platform 13, Specifically, the platform 13 has a top 131 and a bottom 132, and the first alignment structure 11 and the second alignment structure 12 are respectively disposed on the top 131 and the bottom 132. The platform 13 also has a plurality of through holes 130, wherein the through holes 130 penetrate the top 131 and the bottom 132.

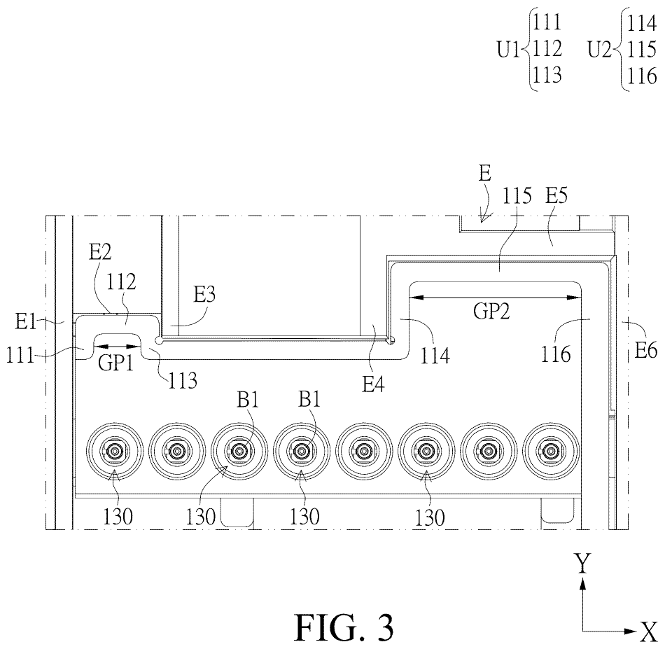

Referring to FIG. 3, FIG. 3 is a schematic top view of the jig module inserted into the mechanism element according to the present disclosure. The first alignment structure 11 includes a first wall 111, a second wall 112, a third wall 113, a fourth wall 114, a fifth wall 115 and a sixth wall 116. The second wall 112 is vertically connected between the first wall 111 and the third wall 113. The first wall 111, the second wall 112 and the third wall 113 together form a first U-shaped portion U1. The fifth wall 115 is vertically connected between the fourth wall 114 and the sixth wall 116. The fourth wall 114, the fifth wall 115 and the sixth wall 116 together form a second U-shaped portion U2. There is a first gap GP1 between the first wall 111 and the third wall 113, a second gap GP2 between the fourth wall 114 and the sixth wall 116, wherein the second gap GP2 is not equal to the first gap GP1.

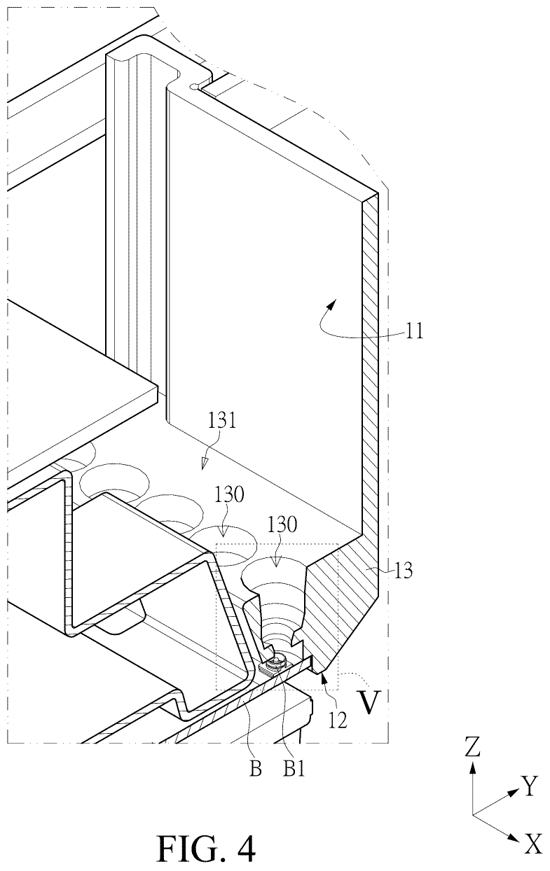

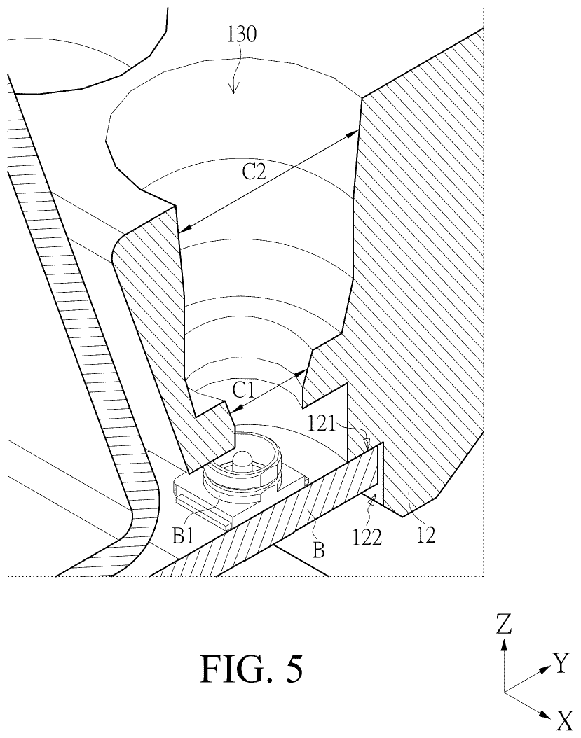

Referring to FIGS. 4 and 5, FIG. 4 is a schematic cross-sectional view of the guiding fixture inserted into the mechanism element according to the present disclosure, and FIG. 5 is an enlarged schematic view of the V portion in FIG. 4. The second alignment structure 12 has a first abutment surface 121 and a second abutment surface 122, the first abutment surface 121 is vertically connected to the second abutment surface 122. The hole diameter of at least one through hole 130 tapers from the top 131 of the platform 13 to the bottom 132 of the platform 13; specifically, the through hole 130 has a first hole diameter C1 located near the bottom 132 and a second hole diameter C2 located near the top 131, where the first aperture C1 is smaller than the second aperture C2.

Furthermore, the first alignment structure 11 and the second alignment structure 12 belong to a peripheral structure of the guiding jig 1, and are designed corresponding to the internal structure of the mechanism element E. As shown in FIG. 3, for example, the mechanism element E has an adapting structure corresponding to the first alignment structure 11, for example, two grooves corresponding to the contour shapes of the first U-shaped portion U1 and the second U-shaped portion U2, wherein one of the grooves is composed of a first groove wall E1, a second groove wall E2, and a third groove wall E3, while the other groove is composed of a fourth groove wall E4, a fifth groove wall E5, and a sixth groove wall E6.

Therefore, when the guiding jig 1 is disposed inside the mechanism element E, alignment is conducted between the first alignment structure 11 and the mechanism element E along a first direction (the direction parallel to the X1 axis) and a second direction (the direction parallel to the Y-axis); that is, the first U-shaped portion U1 and the second U-shaped portion U2 are respectively clamped in the two grooves. The first wall 111 and the third wall 113 of the first U-shaped portion U1 respectively abut against the first groove wall E1 and the third groove wall E3 to achieve the position-limiting in the X-axis direction. The second wall 112 of the first U-shaped portion U1 abuts against the second groove wall E2 to achieve position-limiting in the Y-axis direction. The fourth wall 114 and the sixth wall 116 of the second U-shaped portion U2 respectively abut against the fourth groove wall E4 and the sixth groove wall E6 to achieve position-limiting in the X-axis direction. The fifth wall 115 of the second U-shaped portion U2 abuts against the fifth groove wall E5 to achieve position-limiting in the Y-axis direction. In addition, the design of the first U-shaped portion U1 and the second U-shaped portion U2 having different sizes (that is, the second gap GP2 and the first gap GP1 are not equal) can form a fool-proof structure, such that the guiding jig 1 can be positioned in the correct orientation inside the mechanism element E.

As shown in FIG. 5, for example, the second alignment structure 12 is aligned with the circuit board B along a third direction (the direction parallel to the Z-axis). Furthermore, if the test point B1 of the circuit board B is located at the edge of the circuit board B, the second alignment structure 12 can also be aligned with the circuit board B along the second direction. The first direction, the second direction and the third direction are perpendicular to each other, and the third direction is parallel to the travel direction D (see FIG. 1). Specifically, when the second alignment structure 12 is aligned with the circuit board B, the first abutment surface 121 abuts against the edge of the circuit board B to achieve position-limiting in the Z-axis direction; the second abutment surface 122 abuts against the edge of circuit board B to achieve position-limiting in the Y-axis direction.

Therefore, through the design of the first alignment structure 11 and the second alignment structure 12, the guiding jig 1 can align with internal structures of the mechanism element E in the X-Y plane, and align with the circuit board B in the Y-Z plane (that is, alignment can be performed in the X-axis, Y-axis and Z-axis directions), thereby ensuring the accuracy of the relative positions of the guiding jig 1 with the mechanism element E and the circuit board B. As shown in FIGS. 3 and 4, after completing the alignment between the guiding jig 1, the mechanism element E and the circuit board B, a plurality of through holes 130 of the platform 13 are aligned with a plurality of test points B1 on the circuit board B.

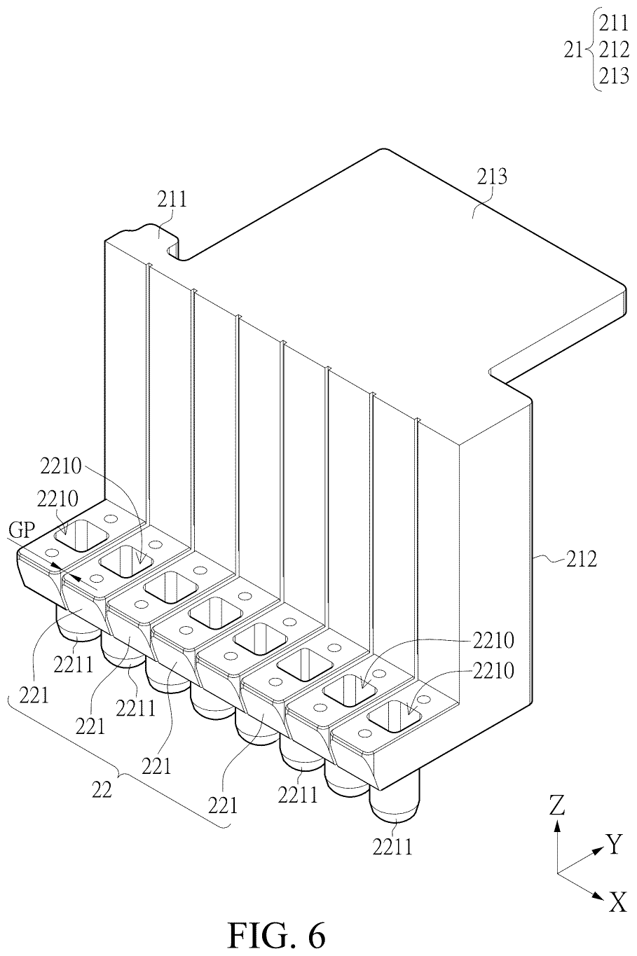

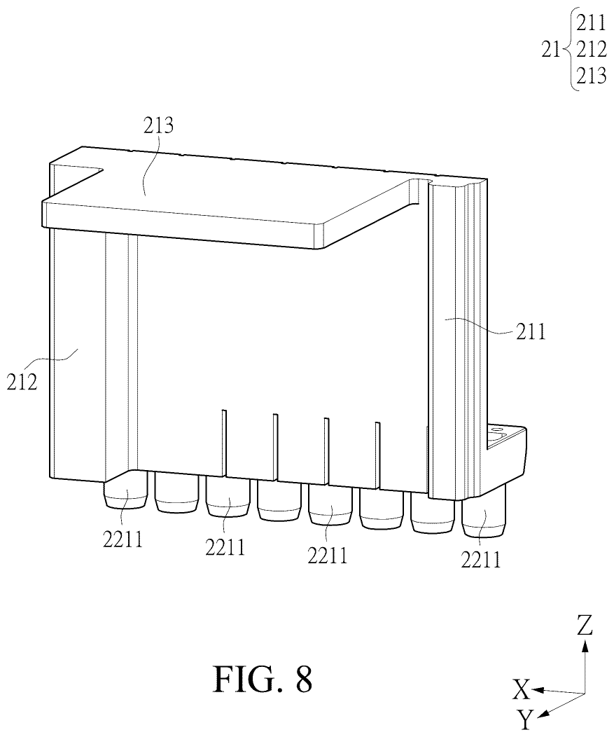

Referring to FIGS. 2, 6 and 8, FIG. 6 and FIG. 8 are schematic views of a probe carrier according to the present disclosure from different viewing angles. After completing the alignment between the guiding jig 1 with the mechanism element E and the circuit board B, the probe carrier 2 can then be assembled into the guiding jig 1 along the travel direction D. The probe carrier 2 can carry a plurality of probe components P. The probe carrier 2 includes a third alignment structure 21 and a stage 22, where the third alignment structure 21 is disposed on the stage 22. The third alignment structure 21 includes a first convex part 211, a second convex part 212 and a stopper part 213, where the stopper part 213 is disposed between the first convex part 211 and the second convex part 212.

It is worth mentioning that the first U-shaped portion U1 and the second U-shaped portion U2 have a concave-convex structure, with the convex structure on the side facing the mechanism element E and a concave structure on the side facing away from the mechanism element E. The first U-shaped portion U1 and the second U-shaped portion U2 align with the mechanism element E via the convex side, and align with the probe carrier 2 via the concave side. Therefore, when the probe carrier 2 is assembled to the guiding jig 1 along the travel direction D, the first convex part 211 is engaged in the concave side of the first U-shaped portion U1, and the second convex part 212 is engaged in concave side of the second U-shaped portion U1, so as to achieve alignment in the first direction (the direction parallel to the X-axis) and the second direction (the direction parallel to the Y-axis). Further, the stopper part 213 abuts against a top surface 110 of the first alignment structure 11 to achieve alignment in the third direction (the direction parallel to the Z-axis). In addition, when the probe carrier 2 is assembled to the guiding jig 1 along the travel direction, the columns 2211 of a plurality of cantilever bearing sections 221 are respectively inserted into the plurality of through holes 130.

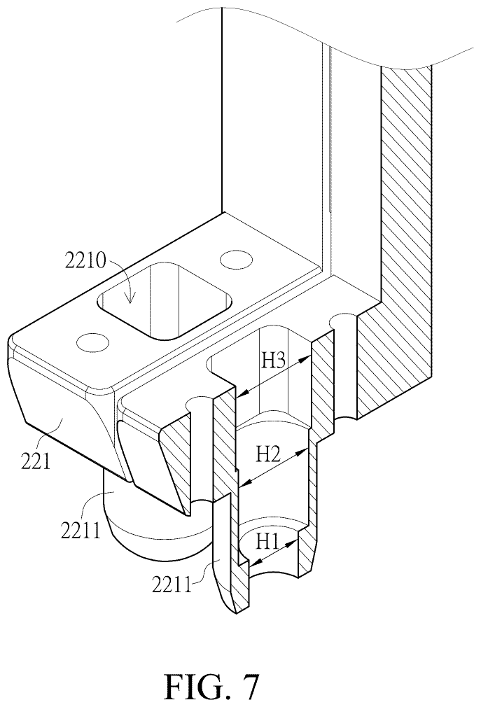

Referring to FIGS. 2, 6 and 7, FIG. 7 is a schematic cross-sectional view of the probe carrier according to the present disclosure. The stage 22 includes a plurality of cantilever bearing sections 221, where there is a fixed gap GP between two adjacent cantilever bearing sections 221. Therefore, each cantilever bearing section 221 can operate independently without being affected by adjacent cantilever bearing sections 221. In addition, the plurality of cantilever bearing sections 221 are made of elastic materials (such as plastic or rubber). At least one cantilever bearing section 221 has a position-limiting hole 2210 and a column 2211, where the position-limiting hole 2210 penetrates through the bottom of the column 2211 along an extension direction of the column 2211. Preferably, in the present disclosure, each cantilever bearing section 221 has a position-limiting hole 2210 and a column 2211. A plurality of probe components P are respectively inserted into a plurality of position-limiting holes 2210.

As shown in FIGS. 2, 3 and 7, the position-limiting hole 2210 has a first hole diameter H1, a second hole diameter H2 and a third hole diameter H3. The position of the second hole diameter H2 is between the position of the first hole diameter H1 and the position of the third hole diameter H3; the position of the first hole diameter H1 is near the bottom of the column 2211, and the position of the third hole diameter H3 is located inside the stage 22 (i.e., at the top of column 2211). The first hole diameter H1 is smaller than the second hole diameter H2, and the second hole diameter H2 is smaller than the third hole diameter H3. In other words, the hole diameter of the position-limiting hole 2210 tapers from the top of the column 2211 to the bottom of the column 2211. Since the third hole diameter H3 on the uppermost side of the position-limiting hole 2210 is larger, the probe components P can be easily inserted therein. Furthermore, the position of the probe components P inserted into the holes can be limited through the tapered aperture design of the position-limiting holes 2210, such that the probe components P will not shake. Since the plurality of through holes 130 of the platform 13 have been aligned with the plurality of test points B1 on the circuit board B, the plurality of probe components P inserted into the plurality of position-limiting holes 2210 can respectively be accurately aligned with and electrically contact a plurality of test points B1, so as to conduct electrical testing.

Therefore, the probe carrier 2 can achieve alignment with the guiding jig 1 in the X-axis, Y-axis and Z-axis directions through the third alignment structure 21, and allow the probe components P to be accurately aligned with the test point B1 through the tapered aperture design of position-limiting holes 2210 of the stage 22, so as to improve the yield of connected electrical testing.

In addition, it should be noted that since there are tolerances in the manufacturing of the mechanism element E and the guiding jig 1, even when the probe carrier 2 is aligned through the third alignment structure 21 and assembled to the guiding jig 1, it is still possible that the effects of tolerances cannot be completely eliminated. That is to say, when the probe carrier 2 is assembled downward onto the guiding jig 1, the probe components P may not directly face the through holes 130. The probe components P and the through holes 130 may still have some deviations on the horizontal direction perpendicular to the assembly direction. Therefore, in the present disclosure, the cantilever bearing sections 221 have an independently-operable and flexible structural design, such that the probe components P being assembled to the guiding jig 1 can still be smoothly inserted into the through holes 130 via the assistance of the structural design of the cantilever bearing sections 221, even if there is a horizontal deviation affecting the assembly.

The present disclosure provides a circuit board testing method carried out by using the guiding jig 1 and the probe carrier 2 according to the present disclosure; the guiding jig 1 and the probe carrier 2 have been described in detail above and will not be repeated herein. The circuit board testing method provided by the present disclosure at least includes the following steps (vide FIGS. 1 to 7):

Step 1: providing a guiding jig 1 being disposed inside a mechanism element E along a travel direction D. The mechanism element E has a circuit board B disposed therein. The guiding jig 1 comprises: a platform 13, a first alignment structure 11 and a second alignment structure 12. The platform 13 includes a plurality of through holes 130 penetrating a top 131 and a bottom 132 of the platform 13. The first alignment structure 11 and the second alignment structure 12 are respectively disposed on the top 131 and the bottom 132 of the platform 13.

Step 2: adjusting the first alignment structure 11, such that it aligns with the mechanism element E along a first direction (the direction parallel to the X-axis) and a second direction (the direction parallel to the Y-axis).

Step 3: adjusting the second alignment structure 12 and the circuit board B to align along a second direction and a third direction (the direction parallel to the Z-axis), such that the plurality of through holes 130 are aligned with a plurality of test points B1 on the circuit board B.

Step 4: providing a probe carrier 2 to carry a plurality of probe components P.

Step 5: assembling the probe carrier 2 carrying a plurality of probe components P into the guiding jig 1, such that the plurality of probe components P respectively pass through the plurality of through holes 130, and are respectively electrically connected to the plurality of test points B1 on the circuit board B.

In addition, Step 3 further includes Step 3-1: further adjusting the second alignment structure 12 and the circuit board B to align along the second direction.

### BENEFICIAL EFFECTS OF THE EMBODIMENTS

The jig module M and circuit board testing method provided by the present disclosure can enable the guiding jig 1 to conduct X-Y plane alignment with the internal structures of the mechanism element E through the design of the first alignment structure 11 of the guiding jig 1; and enable the guiding jig 1 to conduct Y-Z plane alignment with the circuit board B through the design of the second alignment structure 12 (that is, the guiding jig 1 can be aligned in the X-axis, Y-axis and Z-axis directions). Thereby, the provided jig module M and circuit board testing method can ensure the accuracy of the relative positions of the guiding jig 1, the mechanism element E, and the circuit board B. After completing the alignment between the guiding jig 1, the mechanism E and the circuit board B, the plurality of through holes 130 of the platform 13 can be aligned with the plurality of test points B1 on the circuit board B, and the probe carrier 2 can achieve alignment with the guiding jig 1 in the X-axis, Y-axis and Z-axis directions through the third alignment structure 21; and through the tapered aperture design of the position-limiting holes 2210 of the stage 22, the probe components P can penetrate the through holes 130 to align with and electrically contact the test points B1, thereby improving the yield of the connected electrical testing.

The contents disclosed above are only the preferred and feasible embodiments of the present disclosure, and do not limit the scope of the present disclosure; therefore, all equivalent technical changes made through utilizing the content in the description and drawings herein are included within the scope of the present disclosure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A jig module, the jig module adapted for a mechanism element having a circuit board disposed therein, the jig module comprising:
a guiding jig, the guiding jig being disposed inside the mechanism element along a travel direction, the guiding jig comprising:
a platform having a top and a bottom, the platform including a plurality of through holes penetrating the top and the bottom; and
a first alignment structure and a second alignment structure, respectively disposed on the top and the bottom of the platform;
wherein, when the guiding jig is disposed inside the mechanism element, the first alignment structure and the mechanism element align along a first direction and a second direction, the second alignment structure and the circuit board align along a third direction, such that the plurality of through holes are aligned with a plurality of test points on the circuit board, wherein the first direction, the second direction and the third direction are perpendicular to each other, and the third direction is parallel to the travel direction.

2. The jig module according to claim 1, wherein the second alignment structure and the circuit board further align along the second direction.

3. The jig module according to claim 2, wherein the second alignment structure has a first abutment surface and a second abutment surface, the first abutment surface being vertically connected to the second abutment surface; wherein, when the second alignment structure is aligned with the circuit board, the first abutment surface abuts against the circuit board along the third direction, and the second abutment surface abuts against the circuit board along the second direction.

4. The jig module according to claim 2, wherein the first alignment structure includes a first wall, a second wall and a third wall, the second wall being vertically connected between the first wall and the third wall, wherein the first wall, the second wall and the third wall together form a first U-shaped portion, and wherein the first wall and the third wall has a first gap in-between.

5. The jig module according to claim 4, wherein the first alignment structure further includes a fourth wall, a fifth wall and a sixth wall, the fifth wall being vertically connected between the fourth wall and the sixth wall, wherein the fourth wall, the fifth wall and the sixth wall together form a second U-shaped portion, and wherein the fourth wall and the sixth wall has a second gap in-between, and the second gap is not equal to the first gap.

6. The jig module according to claim 5, further comprising a probe carrier assembled to the guiding jig along the travel direction, the probe carrier including a third alignment structure, the third alignment structure including a first convex part, a second convex part and a stopper part, the stopper part being disposed between the first convex part and the second convex part; wherein, when the probe carrier is assembled along the travel direction to guiding jig, the first convex part is engaged in the first U-shaped portion, the second convex part is engaged in the second U-shaped portion, and the stopper part abuts against a top surface of the first alignment structure.

7. The jig module according to claim 1, further comprising a probe carrier assembled to the guiding jig along the travel direction, the probe carrier including a stage, the stage including a plurality of cantilever bearing sections, wherein two adjacent cantilever bearing sections have a fixed gap in-between, at least one of the plurality of cantilever bearing sections has a position-limiting hole and a column, the position-limiting hole penetrating a bottom portion of the column along an extending direction of the column; wherein, when the probe carrier is assembled to the guiding jig along the travel direction, the column of the at least one cantilever bearing section is inserted into at least one of the plurality of through holes.

8. The jig module according to claim 7, wherein the position-limiting hole has a first hole diameter, a second hole diameter and a third hole diameter, the first hole diameter being smaller than the second hole diameter, and the second hole diameter being smaller than the third hole diameter, the second hole diameter being located between the first hole diameter and the third hole diameter, the first hole diameter being located close to the bottom portion of the column, and the third hole diameter being located inside the stage.

9. The jig module according to claim 1, wherein at least one of the plurality of through holes has a first hole diameter located near the bottom, and a second hole diameter located near the top, the first hole diameter being smaller than the second hole diameter.

10. A circuit board testing method, comprising at least the following steps:
providing a guiding jig, the guiding jig being disposed inside the mechanism element along a travel direction, the mechanism element having a circuit board disposed therein, the guiding jig comprising: a platform, a first alignment structure and a second alignment structure, the platform including a plurality of through holes penetrating a top and a bottom of the platform, the first alignment structure and the second alignment structure respectively being disposed on the top and the bottom of the platform;
adjusting the first alignment structure to align with the mechanism element along a first direction and a second direction;
adjusting the second alignment structure to align with the circuit board along a third direction, such that the plurality of through holes are aligned with a plurality of test points on the circuit board, wherein the first direction, the second direction and the third direction are perpendicular to each other, and the third direction is parallel to the travel direction;
providing a probe carrier to carry a plurality of probe components; and
assembling the probe carrier to the guiding jig, such that the plurality of probe components respectively pass through the plurality of through holes, and are respectively electrically connected to the plurality of test points.

11. The circuit board testing method according to claim 10, wherein the step of adjusting the second alignment structure to align with the circuit board along the third direction such that the plurality of through holes are aligned with the plurality of test points on the circuit board further comprises: further adjusting the second alignment structure to align with the circuit board along the second direction.

12. The circuit board testing method according to claim 10, wherein the probe carrier includes a stage, the stage including a plurality of cantilever bearing sections, wherein two adjacent cantilever bearing sections have a fixed gap in-between, at least one of the plurality of cantilever bearing sections has a position-limiting hole and a column, the position-limiting hole penetrating the column along an extending direction of the column; wherein, when the probe carrier is assembled to the guiding jig along the travel direction, the column of the at least one cantilever bearing section is inserted into at least one of the plurality of through holes.

13. The circuit board testing method according to claim 10, wherein the second alignment structure has a first abutment surface and a second abutment surface, the first abutment surface being vertically connected to the second abutment surface; wherein, when the second alignment structure is aligned with the circuit board, the first abutment surface abuts against the circuit board along the third direction, and the second abutment surface abuts against the circuit board along the second direction.

14. The circuit board testing method according to claim 10, wherein at least one of the plurality of through holes has a first hole diameter located near the bottom, and a second hole diameter located near the top, the first hole diameter being smaller than the second hole diameter.
